(19) United States
(12) Patent Application Publication
(10) Pub. No.: US 2025/0062187 A1
(43) Pub. Date: Feb. 20, 2025

(54) Direct Vapor Chamber for Heat Dissipation in Electronic Devices

(71) Applicant: Yuci Shen, Livermore, CA (US)

(72) Inventor: Yuci Shen, Livermore, CA (US)

(21) Appl. No.: 18/235,851

(22) Filed: Aug. 20, 2023

(51) Int. Cl. H01L 23/427; H01L 23/24; H01L 23/34

(52) U.S. Cl. CPC H01L 23/427; H01L 23/24; H01L 23/345

(57) ABSTRACT

The present disclosure describes an electronic device with a direct vapor chamber, wherein the direct vapor chamber includes a heat generating element, like a flip chip of the electronic device, as a portion of it so that a conventional TIM is avoided when using a conventional vapor chamber. The electronic device, comprising: a flip chip and a direct vapor chamber which includes an upper part, a lower part, a two-phase heat dissipating structure, and a working liquid. The lower part includes the flip chip as a portion of it, the upper part and the lower part form a closed chamber, the two phase heat dissipating structure is formed inside the closed chamber, and the working liquid works in the two phase heat dissipating structure to directly dissipate a heat from the flip chip to the upper part through a phase change manner.

### TECHNICAL FIELD OF THE DISCLOSURE

The disclosure relates generally to an electronic device with a heat dissipating object, and particularly to a flip chip package, wherein a vapor chamber is adopted to quickly dissipate heat from the heat dissipating object to the outside of the vapor chamber.

### BACKGROUND OF THE DISCLOSURE

For a high power electronic device, like a flip chip package integrated with a high power flip chip, a vapor chamber is frequently used to dissipate and spread the heat generated by the flip chip, wherein a thermal interface material (TIM) has to be used to thermally connect the flip chip with the vapor chamber in the prior arts. As a result, an additional thermal resistance from TIM is introduced, causing the flip chip to have an additional temperature rise. To reduce the temperature rise due to TIM, many low thermal resistance TIM have been developed in prior arts, as well as cooling systems that allow for the use of low thermal resistance TIMs like liquid metal; these systems can be seen in some recent inventions such as U.S. Pat. Nos. 10,643,924, 11,296,010, and 11,373,931, and 11,177,193. However, even though a liquid metal TIM can reduce the temperature rise, it is desired to avoid the use of TIMs altogether when using a vapor chamber to dissipate heat from an electronic device.

### SUMMARY OF THE DISCLOSURE

The present disclosure describes an electronic device with a direct vapor chamber, wherein the direct vapor chamber includes a heat generating element of the electronic device as a portion of it so that a conventional TIM is avoided when using a conventional vapor chamber. The electronic device, comprising: a flip chip and a direct vapor chamber which includes an upper part, a lower part, a two-phase heat dissipating structure, and a working liquid. The lower part includes the flip chip as a portion of it, the upper part and the lower part form a closed chamber, the two phase heat dissipating structure is formed inside the closed chamber, and the working liquid works in the two phase heat dissipating structure to directly dissipate a heat from the flip chip to the upper part through a phase change manner. For a specific electronic device, like a flip chip package, one or more additional features are described to form a direct vapor for the specific electronic device. These additional features are further summarized through a lidded flip chip package below.

A lidded flip chip package of one preferred embodiment of the present invention is described, comprising: a substrate, a lid mounted on the substrate, a flip chip mounted on the substrate, a sealing ring, and a direct vapor chamber which includes a lower part, an upper part, a two-phase heat dissipating structure and a working liquid; wherein the lid has a window, the flip chip is exposed from the window, and the sealing ring is positioned at a peripheral edge region of the flip chip to seal a gap between the lid and the flip chip; wherein the lower part comprises of the lid, the sealing ring, and the flip chip, the upper part includes a base plate with a pedestal extending into the window, the upper part and the lower part are assembled together at their peripheral regions so as to form a closed chamber; and wherein the two-phase heat dissipating structure is formed inside the closed chamber, which includes a layer of wick at a top surface of the lower part, and the working liquid works in the two-phase heat dissipating structure to directly dissipate heat from the flip chip to the upper part through a phase change manner.

Some additional features of an electronic device of the present disclosure include that the two-phase heat dissipating structure, which includes a plurality of channels formed at a bottom surface of the upper part, a layer of wick formed through one or more layers of copper meshes or other material and clamped between the upper part and the lower part, a heat generating element that comprises of single chip module or a plurality of separate chips, a direct vapor chamber includes a cooler on its top surface, and others. The advantages of these more features of the preferred embodiments of the present disclosure will become more apparent from the detailed descriptions in conjunction with the drawings below. The drawings and associated descriptions are to illustrate the embodiments of the present disclosure, not to limit the scope of what is claimed . . .

### BRIEF DESCRIPTION OF THE DRAWINGS

FIG. 1 is a schematic diagram for illustrating a conventional vapor chamber and its application for dissipating heat from a heat generating element of prior arts.

FIG. 2 is a schematic diagram for illustrating a basic feature of an electronic device with a direct vapor chamber of the present disclosure.

FIG. 3 is a schematic diagram for illustrating a lidded flip chip package with a direct vapor chamber of one preferred embodiment of the present disclosure.

FIG. 3A is a schematic diagram for illustrating a lidded flip chip package with a direct vapor chamber, wherein a working liquid is directly dissipating heat from a flip chip of the lidded flip chip package of one preferred embodiment of the present disclosure.

FIGS. 3B and 3C are schematic diagrams for illustrating some more features of a lidded flip chip package with a direct vapor chamber of another preferred embodiment of the present disclosure.

FIGS. 4 and 4A are schematic diagrams for illustrating a plurality of channels formed in a bottom surface of an upper part of the direct vapor chamber of one preferred embodiment of the present disclosure.

FIGS. 5, 5A, 5B and 5C are schematic diagrams for illustrating an assembly process for making a lidded flip chip package with a direct vapor chamber of one preferred embodiment of the present disclosure.

FIGS. 6, 6A, and 6B are schematic diagrams for illustrating another assembly process for making a lidded flip chip package with a direct vapor chamber of another preferred embodiment of the present disclosure.

FIG. 7 is a schematic diagram for illustrating a two-phase heat dissipating structure in a direct vapor chamber of a lidded flip chip package of one preferred embodiment of the present disclosure.

FIG. 8 is a schematic diagram for illustrating another two-phase heat dissipating structure in a direct vapor chamber of a lidded flip chip package of one embodiment of the present disclosure.

FIG. 9 is a schematic diagram for illustrating a direct vapor chamber with a cooler on its top side of one embodiment of the present disclosure.

FIGS. 10 10A and 10B are schematic diagrams for illustrating an assembly process for making an electronic device with a direct vapor chamber of one preferred embodiment of the present disclosure.

FIG. 11 is a schematic diagram for illustrating another flip chip package with a direct vapor chamber of one embodiment of the present disclosure.

FIGS. 11A, 11B, 11C, 11D and 11E are schematic diagrams for illustrating some more features of a flip chip package with a direct vapor chamber of one preferred embodiment of the present disclosure.

FIG. 12 and FIG. 12A are schematic diagrams for illustrating a flip chip package with a direct vapor chamber of another preferred embodiment of the present disclosure.

### DETAILED DESCRIPTION OF THE PREFERRED EMBODIMENT

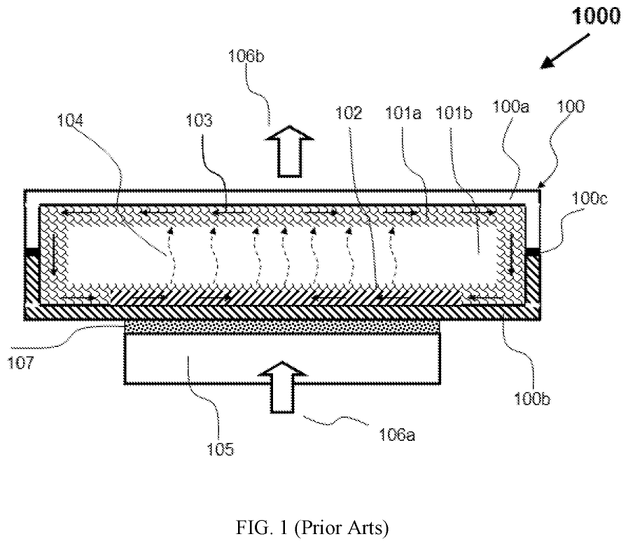

FIG. 1 is a schematic diagram for illustrating how a conventional vapor chamber is used to dissipate heat from an electronic device of prior arts. The numerical symbol 1000 in FIG. 1 designates a cross-sectional view of a conventional vapor chamber 100, a heat generating element 105, like a flip chip of an electronic device, and a thermal interface material (TIM) 107. The vapor chamber 100 includes an upper part 100a and a lower part 100b, which are bonded together (as illustrated by the bonding line 100c which is usually a metal to metal welding, depending on the manufacturing method) to form a closed chamber 100a/100b/100c. The closed chamber 100a/100b/100c is also called a shell or envelope. The upper part 100a and the lower part 100b of the conventional vapor chamber are usually made from a copper shell. A two-phase heat dissipating structure 101a/101b and a working liquid 102 are formed inside the closed chamber 100a/100b/100c, wherein the 101a designates a lining of wick on an inner surface of the closed chamber 100a/100b/100c, the 101b designates a space or a chamber, and the working liquid 102 includes a vapor phase 104 and a liquid phase 103, as illustrated by the dash wave arrows 104 and the solid arrows 103, respectively. When the flip chip 105 is generating heat, the temperature of the lower part 100b is higher because it is heated by the flip chip 105, while the temperature of the upper part 100a is lower because it is cooled by a cooler (not depicted here for simplicity) mounted on a top side of the vapor chamber 100. The arrows 106a and 106b respectively illustrate heat flow from the flip chip 105 to the vapor chamber via the TIM 107, and the vapor chamber 100 to an ambient. As illustrated by the dash wave arrows 104, the working liquid 102 gets vaporized in a lower layer of wick attached on the lower part 100b and moves to an upper layer of wick attached on the upper part 100a via the space 101b. And as illustrated by the solid arrows 103, the working liquid 102 gets condensed in the upper layer of wick and moves back to the lower layer of wick via a capillary action along the lining of wick 101a. In such a way, the vapor chamber 100 dissipates heat from the flip chip 105 from its lower part to its upper part and then to an ambient by a cooler. It is noted that a thermal resistance of TIM 107 will cause the flip chip 105 to have an additional temperature rise during such a heat dissipating process. The temperature rise can be very high when the flip chip has a high power flux.

It is noted that a conventional vapor chamber is usually used together with a cooler or as a portion of a cooler, like a heatsink or a cold plate, and is manufactured by the cooler industry. Meanwhile, an electronic device, like a flip chip package, is manufactured by the semiconductor industry. Since they are manufactured separately and then assembled together, a thermal interface material (TIM) has to be used when assembling them together for a heat dissipation of a flip chip package. In the present invention, a direct vapor chamber is described, which is formed when designing and assembling a flip chip package, wherein a flip chip or a heat generating element is designed as a portion of the direct vapor chamber, and does not need a TIM or additional assembly.

It is also noted that if an element in a later figure is the same as one in a previous figure, the element may share the same numerical symbol as that in the previous figure. The same numerical symbol may not be marked out in the later figure and the same element may not be repeatedly described for simplicity and clarity.

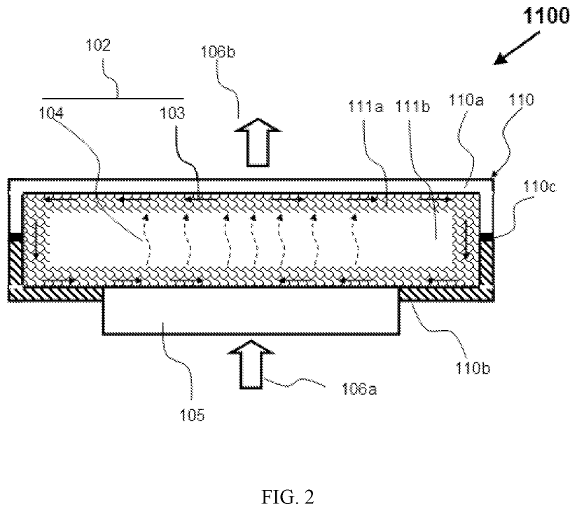

FIG. 2 is a schematic diagram for illustrating a basic feature of an electronic device with a direct vapor chamber of the present invention, in which the numerical symbol 1100 designates a cross-sectional view of an electronic device or a flip chip 105 integrated with a direct vapor chamber 110, including an upper part 110a, a lower part 110b, a two-phase heat dissipating structure 111a/111b, and a working liquid 102; wherein the lower part 110b includes the flip chip 105 as a portion of it; and the upper part 110a and the lower part 110b form a closed chamber via a bonding 110c along their peripheral regions; wherein the two-phase heat dissipating structure 111a/111b is formed inside the closed chamber; the 111a designates a lining of wick attached on an inner surface of the closed chamber for a liquid to flow based on a capillary action, as illustrated by the solid arrows 103, the 111b designates a space or chamber for a vapor generated in a lower layer of wick on the lower part 110b to move to an upper layer of wick on the upper part 110a, that is, from a hot place to a cold place, as illustrated by the dash wave arrows 104; and wherein the working liquid 102 works in the two-phase heat dissipating structure 111a/111b to directly dissipate heat from the heat generating element or flip chip 105 to the upper part 110a through a phase change manner.

It is noted that the basic feature of the present invention is described in conjunction with the drawing in FIG. 2. When the basic feature is used for a specific application, like a flip chip package of one preferred embodiment of the present invention, some other features are needed to design a lidded flip chip package with a direct vapor chamber, which are described in the following.

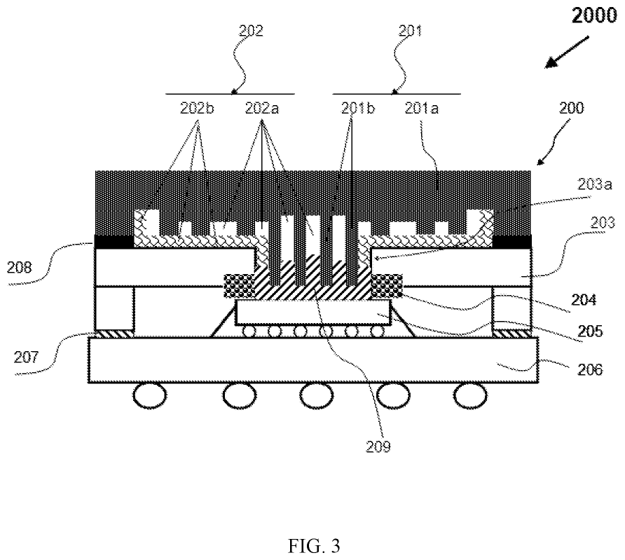

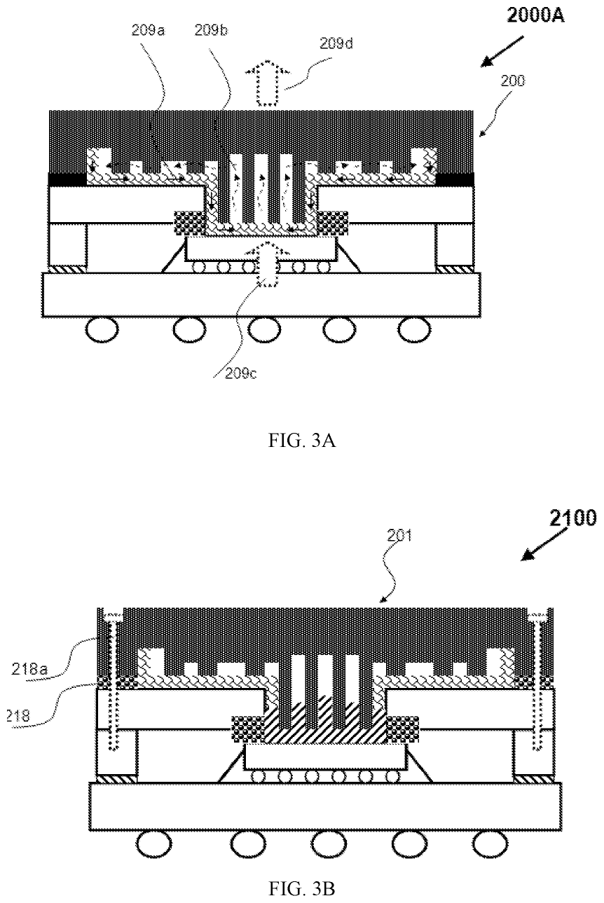

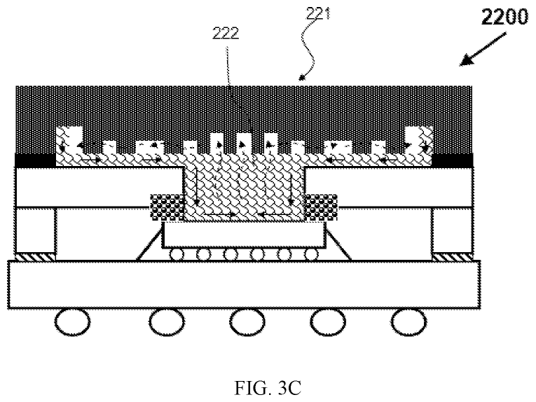

FIG. 3 is schematic diagram for illustrating a lidded flip chip package integrated with a direct vapor chamber of one preferred embodiment of the present invention, in which the numerical symbol 2000 designates a cross-sectional view of a lidded flip chip package integrated with a direct vapor chamber, comprising: a substrate 206, a lid 203 mounted on the substrate 206, a flip chip 205 mounted on the substrate 206, a sealing ring 204, and a direct vapor chamber 200 including a lower part 203/204/205, an upper part 201, a two-phase heat dissipating structure 202, and a working liquid 209; wherein the lid 203 has a window 203a, the flip chip 205 is exposed from the window 203a, and the sealing ring 204 is positioned at a peripheral edge region of the flip chip to seal a gap between the lid 203 and the flip chip 205 along the window 203a; wherein the lower part 203/204/205 comprises of the lid 203, the sealing ring 204, and the flip chip 205, the upper part 201 includes a base plate 201a with a pedestal 201b extending into the window 203a, the upper part and the lower part are assembled together at their peripheral regions through an adhesive, a direct bonding, or another sealing ring 208 so as to form a closed chamber; and wherein the two-phase heat dissipating structure 202 is formed inside the closed chamber, which comprise of a layer of wick 202b at a top surface of the lower part 203/204/205, a plurality of channels 202a formed at a bottom surface of the base plate 201a, and the working liquid 209 works in the two-phase heat dissipating structure 202 to directly dissipate heat from the flip chip 205 to the upper part 201 through a phase change manner.

FIG. 3A is schematic diagram for illustrating how the working liquid 209 as shown in FIG. 3 works to dissipate heat from the flip chip 205 to an ambient, in which the numerical symbol 2000A designates when the flip chip is generating heat, the working liquid 209 starts to work, wherein the dash arrows 209c and 209d illustrate that the heat generated by the flip chip 205 is dissipated from the flip chip 205 to the upper part 201 by the direct vapor chamber 200, and then to an ambient by a cooler, the solid arrows 209a designates that the working liquid 209 is at a liquid phase and flows back to the flip chip 205 along the layer of wick 202b based on a capillary action, and the dash wave arrows 209b designates that the working liquid 209 is at a vapor phase and flows to the upper part 201 along the channels 202a. It is noted that even though the two-phase heat dissipating structure 202 described in FIG. 3 and FIG. 3A comprises of a layer of wick 202b at a top surface of the lower part 203/204/205 and a plurality of channels 202a formed at a bottom surface of the base plate 201a, it can have other structures, like a lining of wick on the inner side of the closed chamber and a space inside the lining of wick, which will be described in another preferred embodiment of the present invention below.

FIG. 3B and FIG. 3C are schematic diagrams for illustrating another feature of a lidded flip chip package integrated with a direct vapor chamber of another preferred embodiment of the present invention, in which the numerical symbol 2100 designates a lidded flip chip package integrated with a direct vapor chamber, wherein the upper part and the lower part are assembled together through another sealing ring 218 which is compressed or fixed through a plurality of screws 218a; and the numerical symbol 2200 designates a lidded flip chip package integrated with a direct vapor chamber, wherein the upper part 221 doesn't have a pedestal, and the cavity in the window of the lid is filled with a wick material 222.

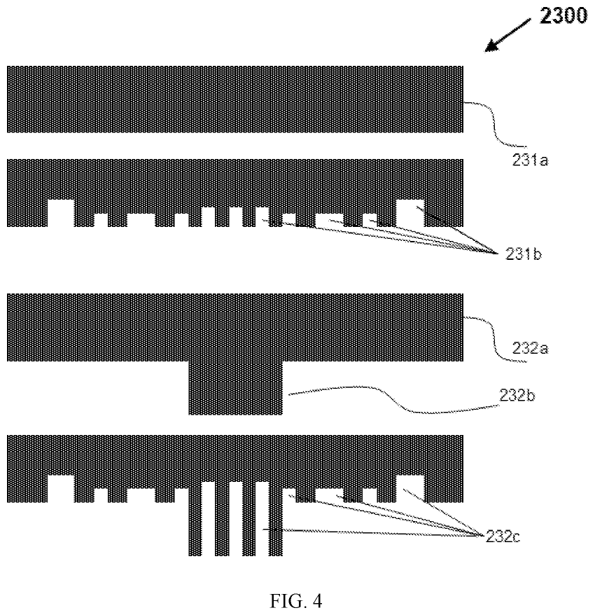

FIGS. 4 and 4A are schematic diagrams for illustrating a structure of the plurality of channels at a bottom surface of the upper parts 201 and 221 as shown in FIG. 3 and FIG. 3C. The numerical symbol 2300 in FIG. 4 illustrates a cross-sectional view of an upper part, in which the 231a designates a base plate, the 231b designates a plurality of channels formed at a bottom side of the base plate 231a, the 232a designates a base plate with a pedestal 232b, and the 232c designates a plurality of channels formed at a bottom side of the base plate 232a. The numerical symbol 2400 designates a bottom view of the upper parts as shown in FIG. 4, in which the 241a designates the base plate, the 241b designates the pedestal, the 241c designates the channels in the pedestal region, the 241d designates the channels outside the pedestal region, wherein the channels 241c in the pedestal region are connected with the outside channels 241d so that a vapor can flows from the pedestal region to the outside region. It is noted that the said pedestal region is a middle region of the base plate above the window of the lid according to the position of the flip chip.

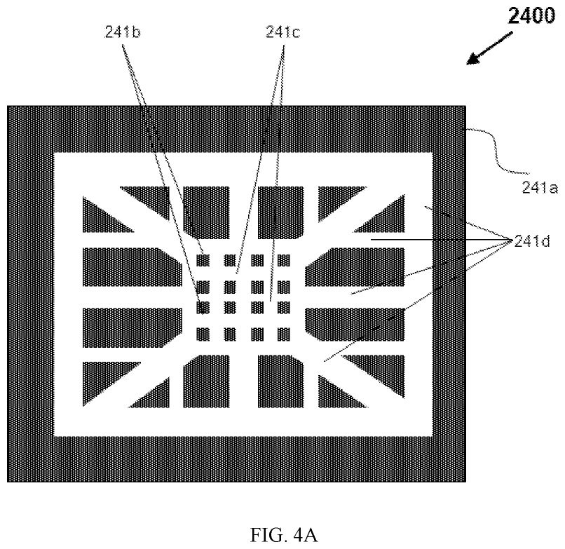

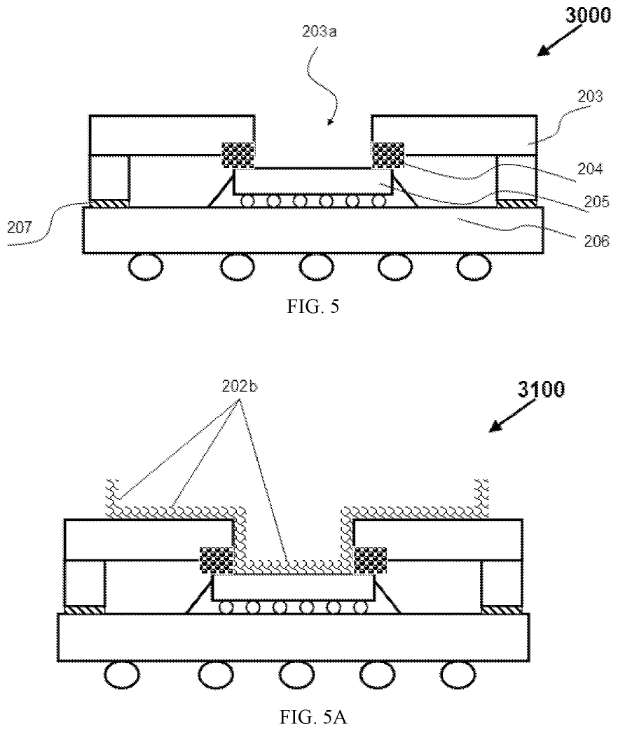

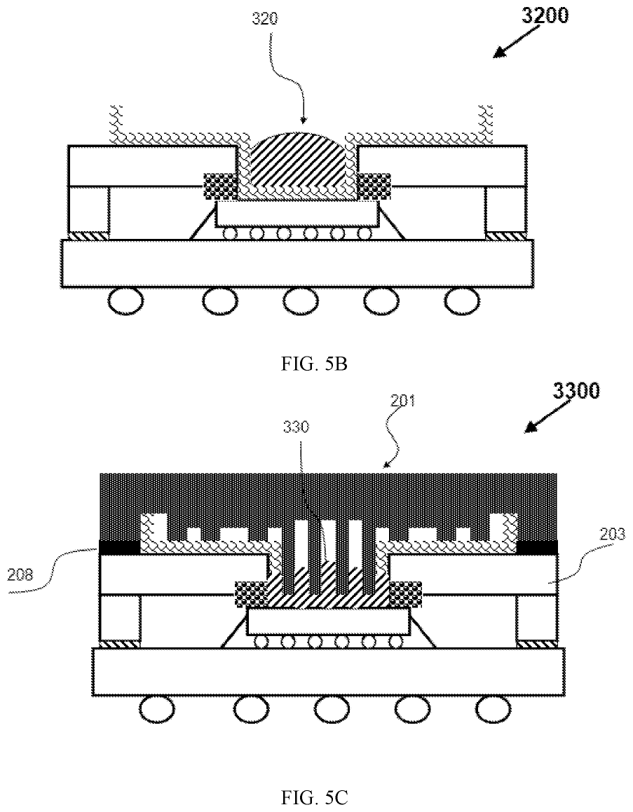

FIGS. 5, 5A, 5B and 5C are schematic diagrams for illustrating an assembly process for making the lidded flip chip 2000 as shown in FIG. 3 of one preferred embodiment of the present invention. The numerical symbol 3000 in FIG. 5 designates the 1st step: the lid 203 with a window 203a is attached on the substrate 206 through an adhesive 207 and over the flip chip 205, wherein the sealing ring 204 is positioned at a peripheral edge region of the flip chip 205 to seal a gap between the lid 203 and the flip chip 205 along an edge of the window 203a. The numerical symbol 3100 in FIG. 5A designates the 2nd step: a layer of wick 202b is placed at a top surface of the lid 203 and flip chip 205. It is noted that an easy way to make the layer of wick 202b.is to use one or more layers of preformed copper meshes. The numerical symbol 3200 in FIG. 5B designates the 3rd step: a working liquid 320 with a desired amount is placed in the layer of wick 202b. The numerical symbol 3300 in FIG. 5C designates the 4th step: the upper part 201 is bonded with the lid at their peripheral regions through an adhesive 208 or other ways to finally form the lidded flip chip 2000 as shown in FIG. 3, wherein the working liquid 320 is enclosed inside the vapor chamber as shown by the 330. It is noted that air should not be trapped inside the direct vapor chamber for the 4th step. One way of accomplishing this is to perform the 4th step under vacuum ambient conditions. Another way is to design a vacuum port in the upper part so that air trapped inside the direct vapor chamber after the 4th step can be removed later.

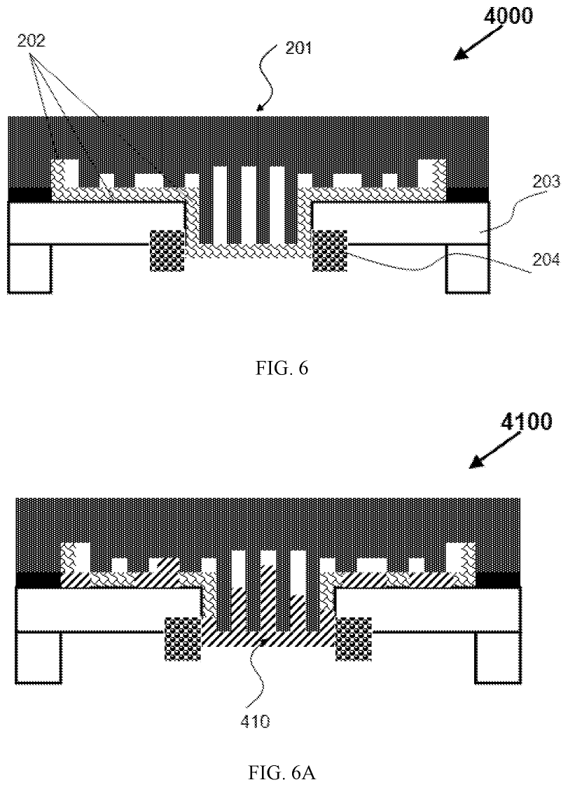

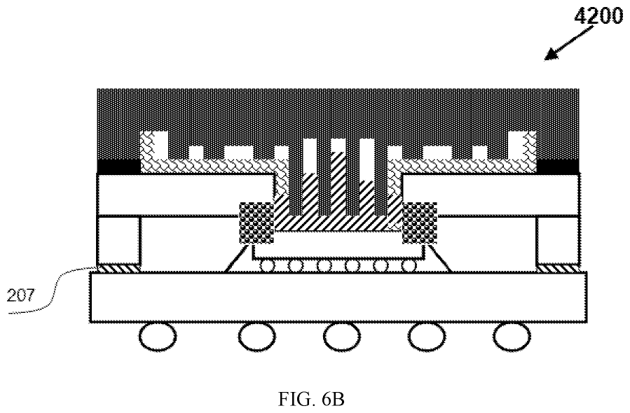

FIGS. 6, 6A and 6B are schematic diagrams for illustrating another assembly process for making the lidded flip chip 2000 as shown in FIG. 3 of another preferred embodiment of the present invention. The numerical symbol 4000 in FIG. 6 designates the 1st step: a lid with a chamber structure for forming the direct vapor chamber is preformed, wherein the lid 203 and the upper part 201 is bonded along their peripheral region, the layer of wick 202 is placed between them, and the sealing ring 204 is attached along the window of the lid 204. The numerical symbol 4100 in FIG. 6A designates the 2nd step: a working liquid 410 is placed inside the chamber structure. The numerical symbol 4200 in FIG. 6B designates the 3rd step: the lid with the vapor chamber filled with the working liquid is attached on the substrate of the flip chip package through an adhesive 207.

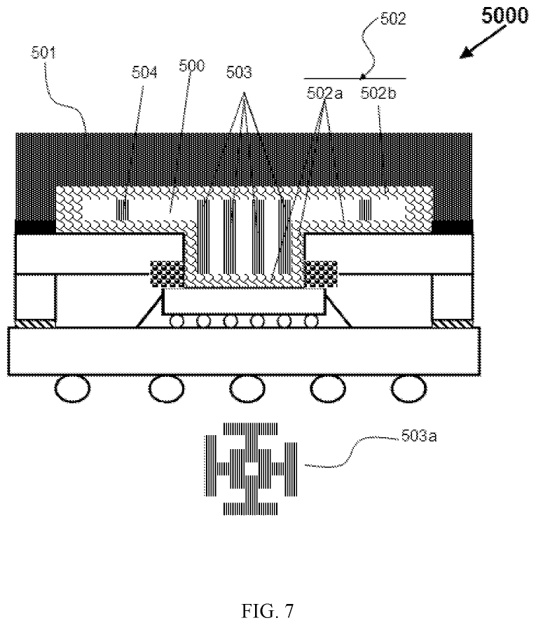

FIG. 7 is a schematic diagram for illustrating another two-phase heat dissipating structure for a direct vapor chamber of one preferred embodiment of the present invention, in which the numerical symbol 5000 designates a cross-sectional view of a lidded flip chip package integrated with a direct vapor chamber, wherein the two-phase heat dissipating structure includes a lining of wick 502 attached on an inner surface of the closed chamber 500, which includes a lower layer of wick 502a on a top surface of the lid and the flip chip and an upper layer of wick 502b on a bottom surface of the upper part 501; and wherein the 503 and 504 designate a spacer with through holes and a plurality of posts interposed between the two layers of wicks 502a and 502b to keep a space for a vapor to move from a hot place to a cold place. The 503a designates a top view of one possible configuration of the spacer 503, where the through holes can be flexibly designed.

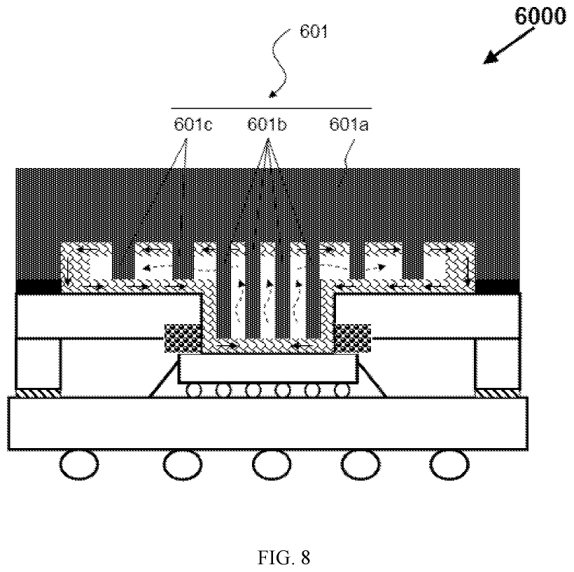

FIG. 8 is a schematic diagram for illustrating another two-phase heat dissipating structure for a direct vapor chamber of one preferred embodiment of the present invention, in which the numerical symbol 6000 designates a cross-sectional view of a lidded flip chip package integrated with a direct vapor chamber, wherein the upper part 601 includes a base plate 601a with a plurality of posts 601b/601c extending down onto the lower layer of wick. The structure of the posts 601b can be flexibly designed. For example, it can be designed similar to the spacer 503a shown in FIG. 7.

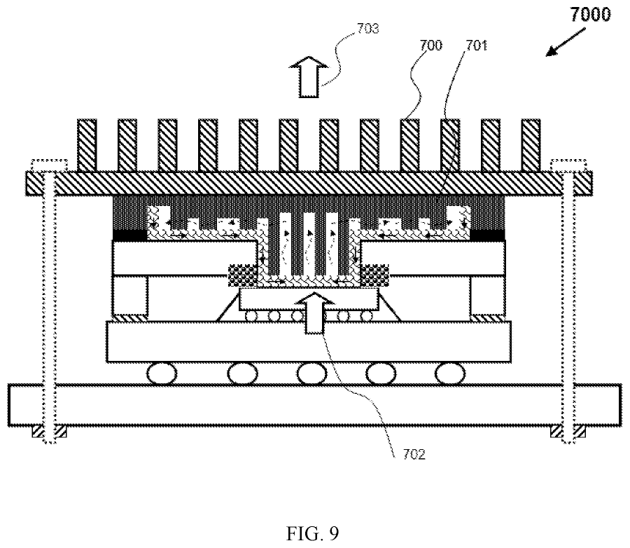

FIG. 9 is a schematic diagram for illustrating an application of a lidded flip chip package with a direct vapor chamber of one preferred embodiment of the present invention, in which the upper part further includes a cooler 700, like a heatsink on a top surface of its base plate 701, the arrows 702 and 703 designate heat flow from the flip chip to an ambient via the direct vapor chamber through a phase change manner as illustrated by the solid and dash wave arrows.

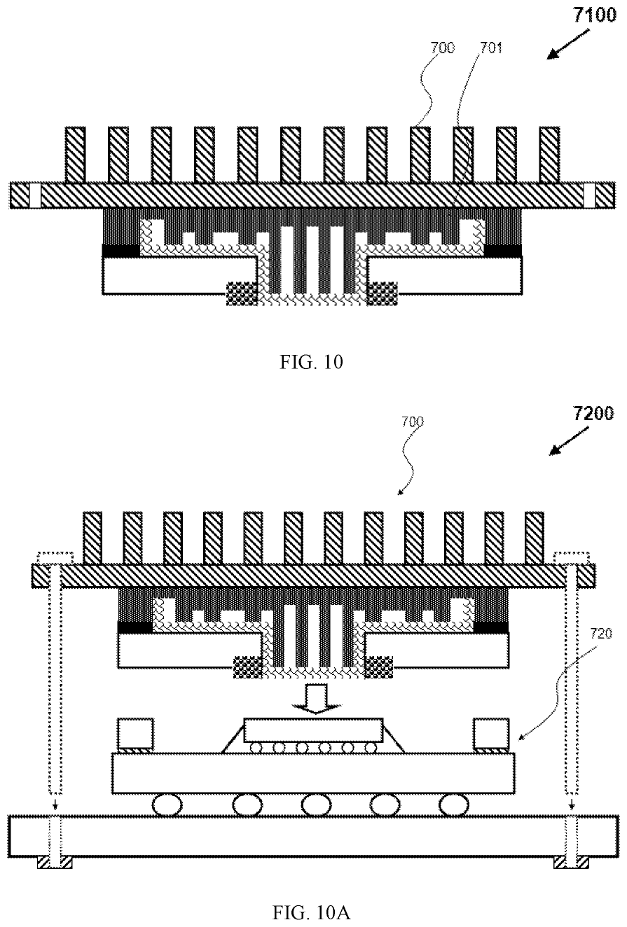

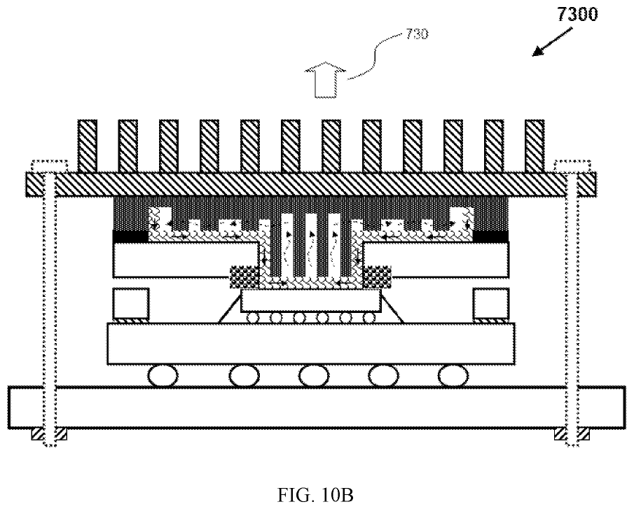

FIG. 10, FIG. 10A and FIG. 10B are schematic diagrams for illustrating an assembly process for making an electronic device with a direct vapor in an application of one preferred embodiment of the present invention, in which the numerical symbol 7100 designates a preformed vapor chamber structure 700 with a cooler 701 on its top side, the numerical symbol 7200 designates that the preformed vapor chamber structure 7100 is attached onto a flip chip package 720, as illustrated by the arrow, and the numerical symbol 7300 designates that the direct vapor chamber is dissipating heat from the flip chip to its upper part through a phase change manner, and then to an ambient by the cooler as illustrated by the arrow 730.

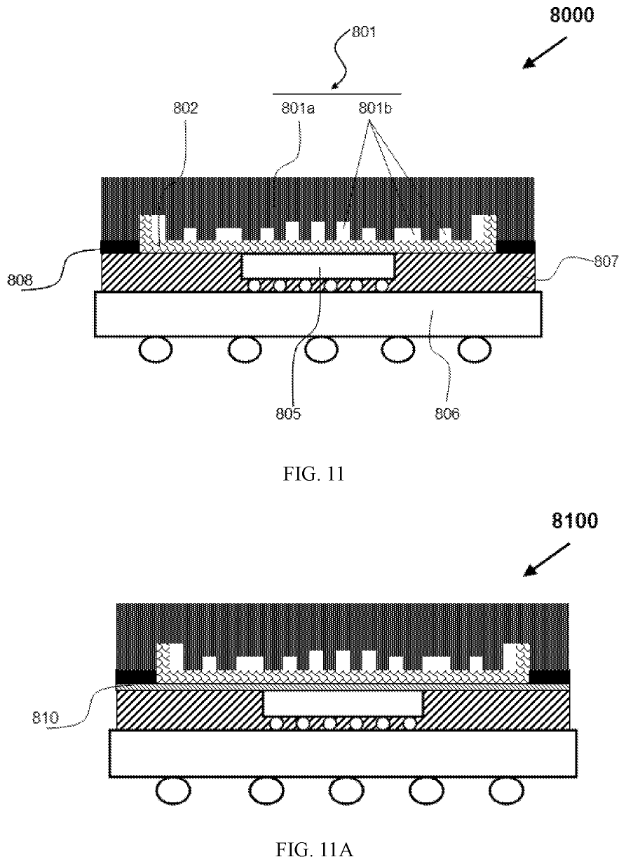

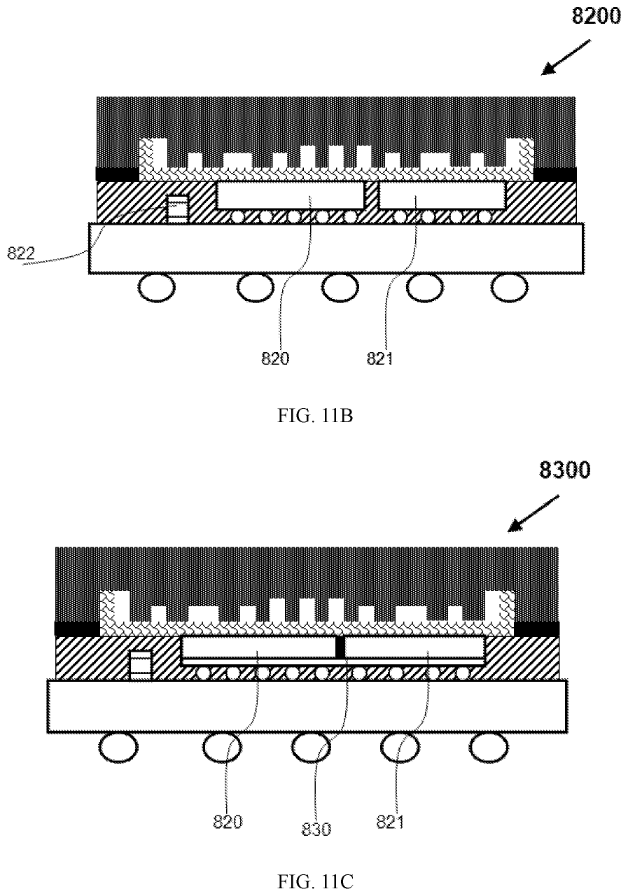

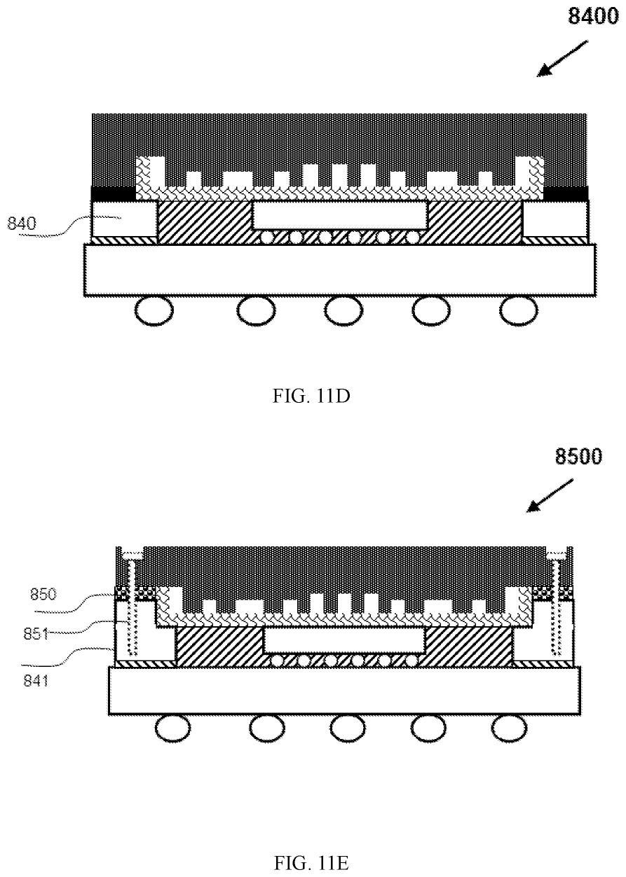

FIG. 11 is a schematic diagram for illustrating a lidded flip chip package integrated with a direct vapor chamber of one preferred embodiment of the present invention, in which the numerical symbol 8000 designates a lidded flip chip package integrated with a direct vapor chamber, which includes an upper part 801 and a lower part 805/806, wherein the lower part 805/806 comprises of a flip chip 805 mounted on a substrate 806 and a molding material 806 covering a top surface of the substrate 806 around the flip chip 805, the upper part 801 includes a base plate 801a with a plurality of channels 801b, and wherein a layer of wick 802 is placed on a top surface of the lower part 805/806 such that the layer of wick 802 and the plurality of channels 801b form a two-phase heat dissipating structure.

FIG. 11A, FIG. 11B, FIG. 11C FIG. 11D and FIG. 11E are schematic diagrams for illustrating some more features of a lidded flip chip package integrated with a direct vapor chamber as shown in FIG. 11 of another preferred embodiment of the present invention. The numerical symbol 8100 in FIG. 11A designates the lidded flip chip package integrated with a direct vapor chamber as shown in FIG. 11, wherein the lower part further includes a metal layer 810 plated on a top surface of the flip chip 805 and the molding material 806. One of the benefits of the metal layer is to isolate the working liquid from the molding material 806. The numerical symbol 8200 in FIG. 11B designates the lidded flip chip package integrated with a direct vapor chamber as shown in FIG. 11, wherein the flip chip 805 comprises of a plurality of chips as illustrated by the chips 820 and 821, as well other components, like one or more capacitors 822, that can also be placed on the substrate and covered by the molding material. The numerical symbol 8300 in FIG. 11C designates the lidded flip chip package integrated with a direct vapor chamber as shown in FIG. 11, wherein the flip chip 805 is a chip module including a plurality of chips 831 and 832 mounted on an interposer 830. The numerical symbol 8400 in FIG. 11D designates the lidded flip chip package integrated with a direct vapor chamber as shown in FIG. 11, wherein the flip chip package further includes a stiffener 840 mounted on a peripheral region of the substrate, the molding material covers a top surface of the substrate between the flip chip and the stiffener, and the lower part includes the flip chip, the stiffener and the molding material. The numerical symbol 8500 in FIG. 11E designates the lidded flip chip package integrated with a direct vapor chamber 8400 as shown in FIG. 11D, wherein a taller stiffener 841 is designed for accommodating screws 851, and the upper part and the lower part are assembled together through another sealing ring 850, which is tightly compressed between the peripheral regions of the two parts through a plurality of screws 851.

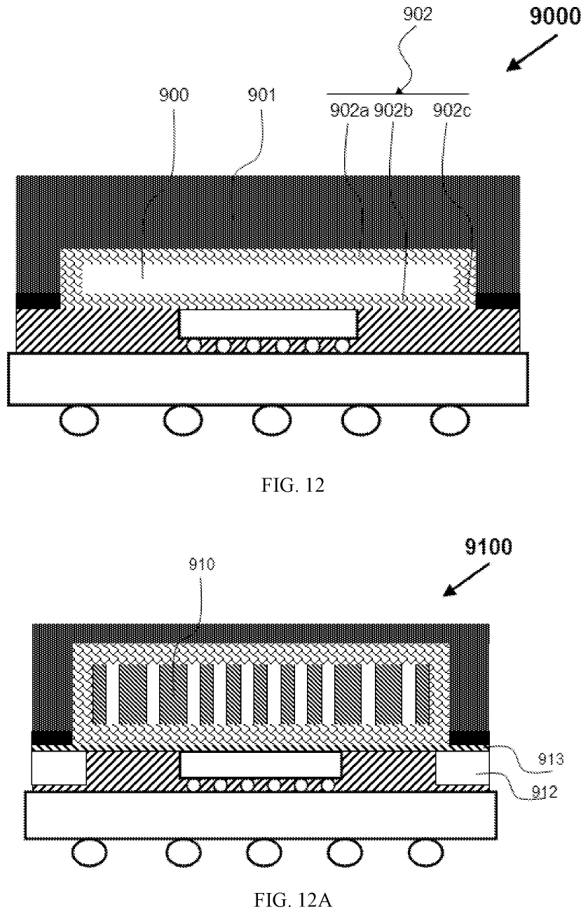

FIG. 12 and FIG. 12A are schematic diagrams for illustrating a lidded flip chip package integrated with a direct vapor chamber of another preferred embodiment of the present invention. The numerical symbol 9000 in FIG. 12 designates a lidded flip chip package integrated with a direct vapor chamber wherein the lower part comprises of a flip chip and a molding material, and a two-phase heat dissipating structure comprises of a lining of wick 902 including an upper layer of wick 902a, a lower layer of wick 902b, a side wick 902c at the inner surface of the closed chamber formed by the upper part and lower part, and a space 900 between the upper layer of wick 902a and the lower layer of wick 902b. The numerical symbol 9100 in FIG. 12A designates the lidded flip chip package integrated with a direct vapor chamber as shown in FIG. 12 further includes some more features, wherein a stiffener 912, a metal layer 913 and a plurality of posts or spacers 910 are integrated with the direct vapor chamber.

The basic feature of the present disclosure is to design a direct vapor chamber, wherein a heat generating element of an electronic device, such as a flip chip, is designed as a portion of a vapor chamber so that a thermal interface material between a conventional vapor chamber and an electronic device is avoided. Many other features are described in conjunction with drawings to achieve the basic feature for a specific electronic device, like a flip chip package, including a lid with a window and a sealing ring for designing a lidded flip chip package with a direct vapor chamber, a flip chip package with a molding material, a two-phase heat dissipating structure comprising of a layer of wick and a plurality of channels, a flip chip comprising of a plurality of chips or a chip module, and so on. It is noted that depending on a specific application, these features can be flexibly combined to design an electronic device with a direct vapor chamber.

Although the present disclosure is described in detail for illustrative purposes with reference to the specific embodiments and drawings, it is apparent that many other modifications and variations may be made without departing from the spirit and scope of the present disclosure.

What is claimed is:

1. An electronic device, comprising: a heat generating element and a direct vapor chamber including an upper part, a lower part, a two-phase heat dissipating structure, and a working liquid;
wherein the lower part includes the heat generating element as a portion of it; and the upper part and the lower part form a closed chamber; and
wherein the two phase heat dissipating structure is formed inside the closed chamber; and the working liquid works in the two phase heat dissipating structure to directly dissipate a heat from the heat generating element to the upper part through a phase change manner.

2. The electronic device of claim 1, further comprising: a substrate, a lid with a window and a sealing ring; wherein the heat generating element is a flip chip mounted on the substrate and exposed from the window, the sealing ring is positioned at a peripheral edge region of the flip chip so as to seal a gap between the lid and the flip chip, and the lower part includes the lid, the flip chip and the sealing ring.

3. The electronic device of claim 1, further comprising: a substrate and a molding material; wherein the heat generating element is a flip chip mounted on the substrate, the molding material covers a top surface of the substrate around the flip chip, and the lower part includes the flip chip and the molding material.

4. The electronic device of claim 1, further comprising: a substrate, a stiffener, and a molding material; wherein the heat generating element is a flip chip mounted on the substrate, the stiffener is mounted on a peripheral region of the substrate, the molding material covers a top surface of the substrate between the flip chip and the stiffener, and the lower part includes the flip chip, the stiffener, and the molding material.

5. The electronic device of claim 1, wherein the two-phase heat dissipating structure includes a plurality of channels formed at a bottom surface of the upper part and a layer of wick clamped between the upper part and the lower part.

6. The electronic device of claim 1, wherein the two-phase heat dissipating structure includes a layer of wick at a bottom surface of the upper part, another layer of wick at a top surface of the lower part, and a space between the two layers of wicks.

7. The electronic device of claim 1, wherein the heat generating element comprises a chip module or a plurality of chips or chiplets.

8. The electronic device of claim 1, wherein the upper part and the lower part are assembled together through an adhesive or a direct welding at their peripheral regions to form the closed chamber.

9. The electronic device of claim 1, wherein the upper part and the lower part are assembled together through another sealing ring at their peripheral regions to form the closed chamber.

10. The electronic device of claim 1, wherein the upper part includes a base plate and a cooler on a top surface of the base plate.

11. The electronic device of claim 1, wherein the working liquid is water.

12. The electronic device of claim 2, wherein the upper part includes a base plate with a pedestal extending into the window.

13. The electronic device of claim 3, wherein the lower part further includes a metal layer plated on a top surface of the flip chip and the molding material.

14. The electronic device of claim 4, wherein the lower part further includes a metal layer plated on a top surface of the flip chip, the stiffener, and the molding material.

15. The electronic device of claim 5, wherein the layer of wick is formed through one or more layers of copper meshes.

16. The electronic device of claim 6, wherein the upper part includes a base plate with a plurality of posts extending into the space between the two layers of wicks.

17. The electronic device of claim 6, wherein one or more spacers are positioned in the space between the two layers of wicks.

18. A lidded flip chip package, comprising: a substrate, a lid mounted on the substrate, a flip chip mounted on the substrate, a sealing ring, and a direct vapor chamber including a lower part, an upper part, a two-phase heat dissipating structure, and a working liquid;
wherein the lid has a window, the flip chip is exposed from the window, and the sealing ring is positioned at a peripheral edge region of the flip chip to seal a gap between the lid and the flip chip;
wherein the lower part comprises of the lid, the sealing ring, and the flip chip, the upper part includes a base plate with a pedestal extending into the window, the upper part and the lower part are assembled together at their peripheral regions so as to form a closed chamber; and
wherein the two-phase heat dissipating structure is formed inside the closed chamber, which includes a layer of wick at a top surface of the low part, and the working liquid works in the two phase heat dissipating structure to directly dissipate a heat from the flip chip to the upper part through a phase change manner.

19. The lidded flip chip package of claim 18, wherein the flip chip comprises a chip module or a plurality of chip lets.

20. The lidded flip chip package of claim 18, wherein the upper part further includes a cooler on a top surface of the base plate.
